(19) United States
(12) Patent Application Publication
(10) Pub. No.: US 2024/0048899 A1
(43) Pub. Date: Feb. 8, 2024

(54) MEMS SOUND TRANSDUCER

(71) Applicant: FRAUNHOFER-GESELLSCHAFT ZUR FOERDERUNG DER ANGEWANDTEN FORSCHUNG E.V., Muenchen (DE)

(72) Inventors: Malte Florian NIEKIEL, Itzehoe (DE); Fabian STOPPEL, Itzehoe (DE); Bernhard WAGNER, Itzehoe (DE); Fabian LOFINK, Itzehoe (DE)

(21) Appl. No.: 18/374,993

(22) Filed: Sep. 29, 2023

Related U.S. Application Data
(63) Continuation of application No. PCT/EP2022/057295, filed on Mar. 21, 2022.

(30) Foreign Application Priority Data
Apr. 1, 2021 (DE) 10 2021 203 360.1

(51) Int. Cl. H04R 1/34; B81B 3/00

(52) U.S. Cl. CPC H04R 1/345; B81B 3/0021; B81B 2201/038; B81B 2203/0109; H04R 2201/003; H04R 31/00

(57) ABSTRACT

An MEMS sound transducer is provided, having: at least one actuator; a radiation structure coupled to the actuator and configured as a separate element; a structure surrounding the radiation structure, wherein the radiation structure is separated from the surrounding structure by one or more gaps; and at least one screen arranged along at least one of the one or more gaps.

### CROSS-REFERENCE TO RELATED APPLICATIONS

This application is a continuation of copending International Application No. PCT/EP2022/057295, filed Mar. 21, 2022, which is incorporated herein by reference in its entirety, and additionally claims priority from German Application No. 10 2021 203 360.1, filed Apr. 1, 2021, which is also incorporated herein by reference in its entirety.

### TECHNICAL FIELD

Embodiments of the present invention relate to an MEMS sound transducer. Embodiments describe a micro-loudspeaker implemented in MEMS technology.

### BACKGROUND OF THE INVENTION

Micro-loudspeakers made of a miniaturization of the well-established electrodynamic drive have evolved as a further development of conventional loudspeakers. In the most widespread moving coil arrangements, a coil is mounted to the back side of the membrane, which moves when applying a current signal in the magnetic field of a fixed permanent magnet and thus deflects the membrane.

One development from the field of hearings aids is the so-called balanced armature transducer (BA transducer). A coil-wound bar is located in the gap of a ring-shaped permanent magnet and connected to a membrane. A current signal on the coil magnetizes the bar on which a torque acts caused by the magnetic field of the permanent magnet. The rotation is transferred to the membrane using a rigid connection. The bar, in its basic state, is in an unstable equilibrium of the magnetic forces of attraction. Due to this unstable state, higher deflections can be obtained with little effort (drive forces, energy). BI transducers thus exhibit higher achievable sound pressure levels and, due to their size, are of advantage for in-ear applications.

Driven by the requirement of miniaturization and inspired by the successes in the field of microphones, microsystems technology has adopted the micro-loudspeaker topic. One development of Fraunhofer ISIT in cooperation with the USound company resulted in an MEMS loudspeaker based on piezoelectric bending actuators which deflect a hybrid-deposited membrane [1]. A loudspeaker module with dimensions of 5.4 mm×3.4 mm×1.6 mm achieves a sound pressure level SPL_{1.4cm}_{³} of at least 106 dB (approximately 116 dB at 1 kHz) over a frequency range of 20 Hz-20 kHz in a sealed volume [2].

A further development of this approach are MEMS loudspeakers based on piezoelectric bending actuators which can do without any additional membranes, developed by Fraunhofer ISIT. Here, the actuators themselves form the acoustically radiating membranes. A loudspeaker chip having an active area of 4 mm×4 mm achieves a sound pressure level SPL_{1.26cm}_{³} of at least 105 dB (approximately 110 dB at 1 kHz) in a sealed space [3].

Various concepts of electrodynamically actuated MEMS loudspeakers are known. Works completed at the Université Paris-Sud and Université du Maine are to be mentioned here [4, 5]. A stiffened Si membrane suspended using Si springs forms a piston-type resonator here. The coil, as a planar coil, is attached directly on the Si membrane and moves the membrane in the magnetic field of a hybrid-deposited permanent magnet.

A related approach, employed by several groups [6, 7, 8, 9, 10, 11], is depositing the planar coil onto a soft polymer membrane, instead of the stiffened Si membrane.

The concept of a magnetostrictively driven micro-loudspeaker is also employed by Albach et al. [12]. The sound transducer here has a setup made of two parts. A micro-loudspeaker chip carrying the magnetostrictive membrane of the loudspeaker is the first part. The membrane itself is made up of many individual bending beams the layer setup of which is made of a magnetostrictive (active) and further passive layers. When applying a magnetic field, these microactuators bend to leave the plane of the chip and thus displace air, thereby generating a sound pressure. The second part of the micro-loudspeaker is formed by a coil through which a current flows, generating the magnetic field used for operation. The concept suggested here provides for a second chip which carries corresponding micro flat coils.

A further micro-loudspeaker concept is based on the nanoscopic electrostatic drive (NED) [23]. The device comprises clamped electrostatic bending actuators; arranged in pairs in rows and columns within the device layer of an SOI (silicon on insulator) wafer and covered by another wafer which is bonded on the SOI wafer at a minute distance. Acoustically effective openings are integrated in the top and bottom sides of the wafer alternatingly between each neighbouring row of actuators to allow sound to be radiated from the device without acoustic short-circuiting.

Another piezoelectrically driven micro-loudspeaker was suggested by xMEMS company. Here, a silicon membrane is driven piezo electrically and caused to vibrate [14].

The best results so far were observed for micro-loudspeakers having a piezoelectric drive. In MEMS loudspeakers which comprise a piezoelectrically driven bending actuator, for example, the limiting factor is the radiation area of the bending actuator. Therefore, there is need for an improved approach.

The object underlying the present invention is providing a concept comprising an improved compromise between manufacturability, radiation characteristic and radiation area (sound pressure achievable).

### SUMMARY

According to an embodiment, an MEMS sound transducer may have: at least one actuator; a radiation structure coupled to the actuator and configured as a separate element; a structure surrounding the radiation structure, wherein the radiation structure is separated from the surrounding structure by one or more gaps; and at least one screen arranged along at least one of the one or more gaps, wherein the at least one screen is formed as part of the radiation structure.

According to another embodiment, a method for manufacturing an inventive MEMS sound transducer as mentioned above may have the steps of: providing at least one actuator and a radiation structure which is coupled to the actuator and configured as a separate element, and a structure surrounding the radiation structure, wherein the radiation structure is separated from the surrounding structure by one or more gaps; and arranging at least one screen along at least one of the one or more gaps.

According to another embodiment, an MEMS sound transducer may have: at least one actuator; a radiation structure coupled to the actuator and configured as a separate element; a structure surrounding the radiation structure, wherein the radiation structure is separated from the surrounding structure by one or more gaps; and at least one screen arranged along at least one of the one or more gaps, wherein the at least one screen is formed as part of the surrounding structure and by a cavity of the surrounding structure; and wherein the at least one screen extends out of a substrate plane or perpendicularly out of a substrate plane, and wherein the at least one screen extends an edge of the cavity.

Embodiments of the present invention provide an MEMS sound transducer comprising at least one actuator (like piezo-based bending actuator), a radiation structure (in the form of a rigid plate, for example) and a structure surrounding the radiation structure. The radiation structure is coupled to the actuator and configured as a separate element to emit sound when actuated by the actuator. The structure surrounding the radiation structure is separated from the surrounding structure by one or more gaps. Additionally, the MEMS sound transducer comprises at least one screen arranged or extending along at least one of the one or more gaps.

Embodiments of the present invention are based on the finding that the loudspeaker performance can be optimized by separating the drive function and the air displacement function. Separating the drive functionality (at least one actuator) and the air displacement functionality (radiation structure) is done by using separate components which can be optimized independently. The active area used for air displacement, for example, can be optimized towards a rigid platform of uniform lifting movement, wherein the maximum deflection of the drive is easier to implement in the displaced volume. Additionally, the active area used for the drive can be optimized for specific circumstances of the drive concept used. Thus, the micro-loudspeakers can be implemented in MEMS technology which, depending on the implementation, makes use of the following advantages:
Higher sound pressure level due to improved air displacement
Lower energy consumption due to optimized active area of the drive
Lower distortions due to improved linearity of the optimized drive
Lower drive voltage due to longer bending actuators

In this way, higher sound pressure levels can be achieved in micro-loudspeakers, with lower energy consumption or equal or smaller dimensions.

In accordance with an embodiment, the radiation structure can be configured to perform, when actuated by the actuator, a lifting or stroke movement in a direction out of the substrate plane. Here, the radiation structure together with the surrounding structure is arranged, for example, within one plane. Exemplarily, the surrounding structure may be formed by a substrate, and the radiation structure may extend in or in parallel to the substrate plane and/or be arranged in a cavity of the substrate. The separation between the radiation structure and the surrounding structure may, as mentioned already, be provided by one or more gaps. These may be circumferential. This circumferential characteristic allows the lifting movement which is not possible in conventional bending actuators. A lifting movement is considerably more efficient since more air can be displaced in this way over the entire bending actuator area.

In accordance with embodiments, the radiation structure may be implemented to be in an idle state relative to the surrounding structure. In accordance with embodiments, the surrounding structure may be idle, i.e. is not actively excited to vibrate. The radiation structure, in contrast, moves relative to the surrounding (idle/immobile) structure. The sound transducer can be connected to a support component (conductive circuit board, electrical components etc.) via the immobile surrounding structure.

With regard to the acoustic separation between the surrounding structure and the radiation structure, it is to be mentioned that one or more screens are used, allowing acoustic decoupling of the back volume of the radiation structure. In accordance with embodiments, at least one screen is formed as part of the radiation structure. Additionally or alternatively, the at least one screen may extend into the substrate plane, for example perpendicularly. Alternatively or additionally, the screen may be formed to be part of the surrounding structure. Here, the screen may, for example, extend out of the substrate plane, for example perpendicularly. In accordance with embodiments, the screen may be formed by a cavity of the circumferential structure.

As has already been mentioned, the gap is advantageously circumferential. In accordance with another embodiment, the screen may also be arranged to be circumferential around the radiation structure or along the one or more gaps.

With regard to the actuator, it is to be mentioned that, in accordance with an embodiment, it is provided as a bending actuator, longitudinal bending actuator or bending actuator having a high aspect ratio. Such a bending actuator allows high lifting movements, at least of the front end. In piezoelectric bending actuators, for example, longer actuators may be used so as to obtain a higher maximum deflection. Limiting the width here provides for a lower capacitive load.

Typically, bending actuators are (exemplarily) provided with a free end and comprise a clamped end (for example at the opposite side). In accordance with an embodiment, the radiation structure is coupled to the free end of the bending actuator. This may, for example, be performed by providing coupling of the radiation structure in the region of the free end. As viewed in the longitudinal direction, the bending actuator may, for example, be coupled in the front third (that is in the third in the longitudinal direction) closer to the free end than to the clamped end. This advantageously allows transferring the maximum stroke to the radiation structure. The actuator or bending actuator may, for example, be a piezoelectrically driven bending actuator. Alternatively, an electrodynamically or electrostatically driven actuator would also be conceivable. Usually, the bending actuator comprises both a suspension function and a drive function relative to the radiation structure.

In accordance with an embodiment, the radiation structure may be supported above the surrounding structure by further elements, like spring elements or springs, for example.

One embodiment is as follows. The radiation structure comprises two or more regions, like four, for example. A central further region is provided between the two or more regions. In accordance with an embodiment, the at least one actuator or more actuators may be coupled to the radiation structure in the central region, for example grip the same. When, in accordance with further embodiments, it is assumed that four regions arranged as quadrants are provided, in accordance with embodiments, the four regions arranged as quadrants may be interrupted by four suspension elements or four actuators/bending transducers (as part of the suspension and as drive). The suspension elements or actuators are coupled to a central region between the four quadrants. The force of four actuators is bundled by this arrangement and the area of four quadrants maximized. Due to the central point of action, the result is a lifting movement, which is of advantage from an efficiency point of view.

### BRIEF DESCRIPTION OF THE DRAWINGS

Embodiments of the present invention will be discussed referring to the appended drawings, in which:

FIG. 1 shows a schematic illustration of an MEMS sound transducer in accordance with a basic embodiment;

FIGS. 2a, 2b show schematic illustrations of an MEMS sound transducer for illustrating screens between platform and substrate and between platform and actuator, in accordance with embodiments;

FIGS. 3a, 3b show schematic illustrations for illustrating screens between platform and actuator and between substrate and actuator, in accordance with embodiments; and

FIGS. 4a, 4b show schematic illustrations of actuators below the platform with screens between actuator and substrate, in accordance with further embodiments.

### DETAILED DESCRIPTION OF THE INVENTION

Before discussing below in greater detail embodiments of the present invention referring to the appended drawings, it is to be pointed out that elements and structures of equal effect are provided with equal reference numerals so that the description thereof is mutually applicable or exchangeable.

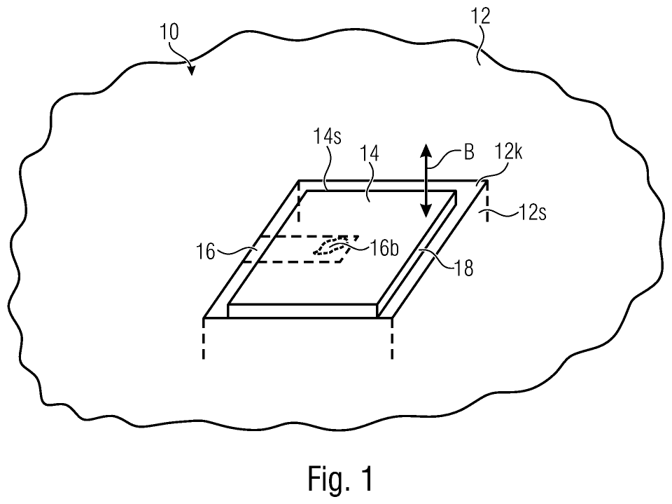

FIG. 1 shows an MEMS sound transducer 10 which is introduced, for example, into a substrate 12. The substrate 12 comprises a cavity 12k. A sound-radiating area 14 is provided in the cavity 12k. The sound-radiating cavity is separated from the structure 12s surrounding the sound-radiating area 14 by a gap 14s, which exemplarily here is arranged to be circumferential around the sound-radiating area 14. The structure 12s surrounding the sound-radiating area is basically formed by the substrate 12 or the walls of the cavity 12k.

The sound-radiating area 14 is supported relative to the surrounding structure 12s by a bending actuator 16 or, generally, an actuator 16. The support is such that the sound-radiating structure 14 is roughly in the substrate plane or can move out of the substrate plane (which is illustrated by the arrow provided with the reference numeral B). Here, the actuator 16 protrudes from the edge of the cavity 12k into the cavity 12k, wherein the sound-radiating area 14 is connected to the actuator 16 in the region 16b. The region 16b is, for example, provided in the front third of the bending actuator 16.

In this embodiment, the sound-radiating area 14 is formed as a flat element, like a flat rectangle or flat disc, for example. The gap 14s is as small as possible to easily separate the back volume, due to laminar flow, at a very small gap. In order to improve this effect, a screen 18 is, for example, provided in the edge region of the sound-radiating area 14. The screen extends perpendicularly to the sound-radiating area 14, for example, like into the substrate plane. In accordance with embodiments, this screen 18 may be circumferential around the radiation area 14. It is to be mentioned here that different forms of the screen 18 would be conceivable, like at the bottom of the sound-radiating area 14, at the top, in the region of the surrounding structure.

Generally, in correspondence with embodiments, the screen is arranged in the region of or along the gap 14s, since it is responsible for acoustic short-circuiting or, when dimensioning the same correctly, is able to prevent acoustic short-circuiting. The technical effect of the screen is that the gap 14s varies along the direction of movement B, also in the case of a lifting movement, here piston stroke, of the sound-absorbing area 14. Providing this screen can provide for this gap to remain as constant as possible. Additionally, due to the piston stroke, it is possible for the gap 14s to be very small since, apart from the vertical movement out of the substrate plane (compare B), there is almost no big movement contribution. This is due to the fact that the bending actuator 16 typically performs a translatory deformation. However, since the sound-radiating area 14 is mounted in the front third (compare reference numeral 16b), the stroke portion of the movement is particularly transferred onto the sound-radiating area. The effect can even be improved when, for example, two bending actuators are arranged opposite each other so that the portion of the radial movement is reduced further. This can, of course, also be achieved by three actuators arranged at angles of 120 degrees, for example, or a different actuator arrangement which allows reducing all portions of movement, except for the stroke or lifting movement.

In particular, coupling the radiation area 14 or air-displacing area 14 and the area of the drive 16 allows optimizing the mean deflection of the active area 14 and, thus, achieves higher sound pressure levels at constant or smaller dimensions. The acoustic function of the air-displacing area 14 is ideally/in correspondence with embodiments optionally implemented as a rigid plate which performs a uniform vertical lifting movement B, which, in detail, means that the deflection of each point on the air-displacing area 14 is equal at each point in time. A possible elongated structural shape is optimum for the bending actuators 16 since the obtained deflections can be maximized and an improved linearity be achieved by this. The elongated actuator has an aspect ratio of 5:1, for example. Since the maximum deflection of the actuator 16 is at its tip, coupling to the rigid plate 14 is to be performed at this position 16b by a suitable structure, like a flexible structure, for example. An optimized geometry would, thus, be a rigid plate 14, performing a stroke movement B, suspended at the longest possible bending actuators 14. The gain results from decoupling of the area used for both functions. The mean deflection of the air-displacing area uses the maximum deflection of the bending actuators 16. Additionally, the ratio of the area used for air displacement to the area used for the bending actuators can be selected as desired and, thus, optimized.

In the piezoelectric bending actuators which are used in this embodiment, other types of driving, like mechanical drive types or electromagnetic drives, are also conceivable. In this case, the requirements to the area 16 entailed for the drive are different. Connecting the air-displacing area, which is optionally implemented as a rigid plate, via a spring suspension to the substrate would be one variation. The spring suspension is similar to the piezoelectric bending actuators described before.

In the concept described before, there are strong relative movements between the air-displacing plate 14, the bending actuators 16 or the spring suspension and a substrate 12 where the plate is suspended via the bending actuators 16 or springs.

When deflected, the gaps 14s may be opened at the edges of the plate 14, which may result in acoustic short-circuiting between front and back volume of the micro-loudspeaker. This may be prevented or optimized by implementing the separation between the elements as narrow gaps. In order to prevent an increase in these gaps even with great deflections, additional screen structures 16b are used. The screen structures may be deposited on the substrate 12 and on the moveable plate 14 or on the deforming bending actuators 16 or spring structures. Depending on the implementation of the concept, providing screens between platform 14 and substrate 12, between platform 14 and spring/actuator 16 and between spring/actuator 16 and substrate 12 is considered. It is to be mentioned here that, while using the cavity 12k in which the platform 14 and the actuators 16/springs are suspended, the substrate itself may also function as a screen. Depending on the direction of movement, the screens 16b are, for example, implemented upwards and/or downwards.

A pre-deflection of the platform in correspondence with embodiments allows implementation of the screens 14b in one direction only, like upwards or downwards, for example.

In the case of such a pre-deflection, the mechanical stress of the springs/actuators 16 is considered. In particular, contraction of the actuators/springs in the lateral direction is to be considered, which is allowed due to the suitable coupling structure. This means that the coupling structure 16b allows preventing expansion of the slots in the lateral direction.

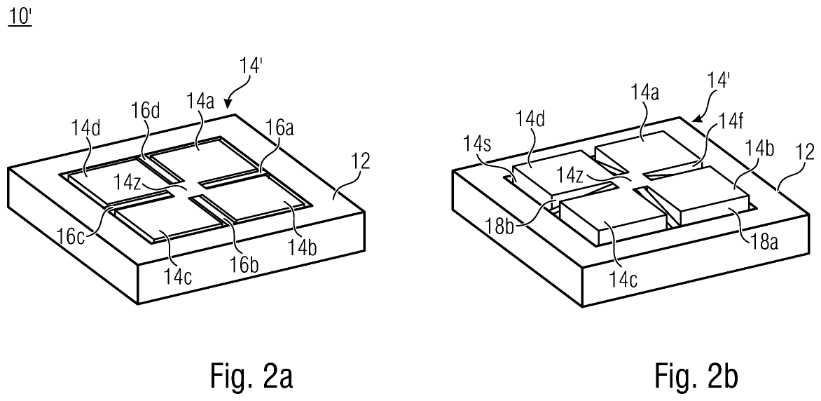

An extended embodiment will be discussed below referring to FIG. 2. FIG. 2 shows an MEMS sound transducer 10′ which is undeflected in illustration A and deflected in illustration B. The MEMS sound transducer comprises a surrounding structure 12, a radiation area 14′ which has four quadrants 14a to 14d. In this embodiment, the area 14′ is driven via four actuators 16a to 16d. These are arranged between the quadrants 14a to 14d as follows. In detail: 16a is provided between 14a and 14b, 16b between 14b and 14c, 16c between 14c and 14d and 16d between 14d and 14a. A kind of slot is provided each between the quadrants 14a to 14d. This slot is purely exemplarily provided with the reference numeral 14f in FIG. 2b.

The bending actuators 16a to 16d act on a central point of the radiation area. The central point or central area is provided with the reference numeral 14z and connects the four quadrants 14a to 14d. As can be recognized in FIG. 2b, the radiation structure 14′ comprises one or more screens 18. The screens 18a, also referred to as external screens, are arranged in the region of the gap 14s and, when viewed from the radiation area 14′, extend downwards into the substrate 12 so that, when deflected, the gap width still remains constant in the stroke direction B. The several screens 18a are, for example, provided at each quadrant at the external edges, that is on the side facing the substrate 12 (that is 4×2). Further screens 18b, which are also referred to as internal screens, are also provided on the inner side in the region 14f, that is adjacent to the bending transducers 16a to 16d. In correspondence with embodiments, only the screens 18a or 18b may also be used.

As can be recognized here, a stroke movement of the radiating unit 14 is performed in the case of deflection, because each bending actuator 16a to 16d results in a deflection of the element 14z, wherein the longitudinal forces compensate one another due to the opposite arrangement of the actuators 16a and 16c and 16b and 16d.

As can be recognized easily, the radiation area 14 formed by the four quadrants 14a, 14b, 16c and 14d and the central element 14z is significantly larger than a radiation area resulting from the bending sound transducers 16a to 16d. Additionally, the bending sound transducers 16a to 16d are implemented to be elongate to obtain a sufficient stroke at the end of the bending transducer, that is opposite the clamped end (transition 16a to 16d to 12). The elements 14′ and 16a to 16d can be optimized independently by this arrangement. In accordance with embodiments, it would, of course, also be conceivable for only two, three or even more bending transducers to be used instead of the four bending transducers 16a to 16d. The geometry of the elements 14a to 14d changes in dependence on this. It is to be mentioned at this point that some components, like the external screens 18a or the internal screens 18b, for example, may also be arranged differently.

It would, for example, be conceivable for screens to be alternatively or additionally arranged in the substrate region 12, for example along the gap 14s surrounding the radiation structure 14′, instead of the (perpendicular) screens 18a and 18b on the deflectable structure 14.

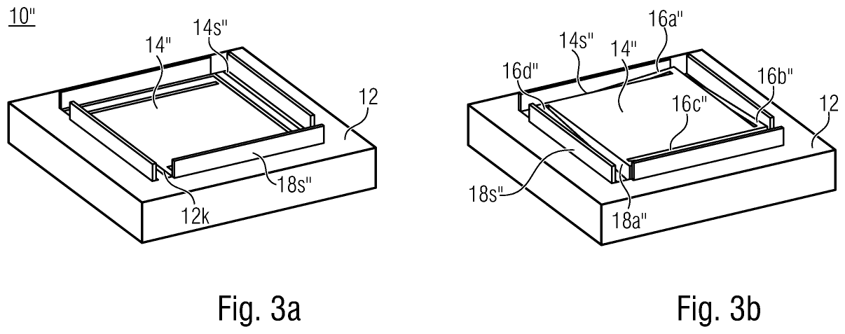

Additionally, the screens may extend not only into the substrate end, but also out of the substrate end. Such an arrangement is shown in FIG. 3.

FIG. 3 shows an MEMS sound transducer 10″ having a radiation structure 14″ which is provided as a rectangular area. The radiation structure 14″ is supported relative to the substrate 12 by four actuators 16a″ to 16d″. The actuators 16a″ to 16d″ extend along the external edge of the radiation structure 14″, i.e. are arranged in the gap 14s″. All the actuators 16a″ to 16d″ in turn are arranged longitudinally and are connected to the substrate 12 or the radiation structure 14″ at the outer most ends of the longitudinal actuator. This in turn results in the advantage of a large radiation area of the radiation structure 14″ and long actuators or bending actuators 16a″ to 16d″ which result in a great stroke. The arrangement of the actuators 16a″ to 16d″ which are oriented to be opposite (cf. 16a″ and 16c″ and 16b″ and 16d″) results not only in a smaller tilting of the radiation structure 14″, but also in particular, in a large stroke portion of the deflection.

With regard to the screens, it is to be mentioned that these may be arranged both in the region of the radiation structure 14″ and in the region of the substrate 12. Exemplarily, both variations are illustrated here, wherein one variation would basically be sufficient. It is to be mentioned here that, in accordance with embodiments, the implementation with both screen variations would be of advantage since both the gap between actuator and substrate and also between actuator and radiation area would expand otherwise.

As can be recognized from the deflected version 3b, the screens 18a″ are located on the outside or circumferentially around the sound-absorbing structure 14″. In this case, that is the quadrangular sound-absorbing structure 14″ having four edges, four screens 18a″ are provided, for example. These provide for sealing relative to the gap 14s″ and, in particular, the gap between the bending actuator 14a″/14b″/14c″/14d″ and the sound-radiating structure 14″. In order to be able to seal the region between the actuator 14a″/14b″/14c″/14d″ and the substrate 12, further screens 18s″ are provided. These screens extend the edge of the cavity 12k in the substrate 12 out of the substrate plane. The elements 18s″ cooperate, for example, with the lateral wall of the cavity 12k and allow the gap to be kept constantly small, when starting from the idle position in FIG. 3, and the upward deflection and downward deflection of the radiating structure 14″.

The screen 18s″ may, as is illustrated here, be interrupted in the region of the fixedly clamped ends of the bending actuators 16a″, 16b″, 16c″ and 16d″.

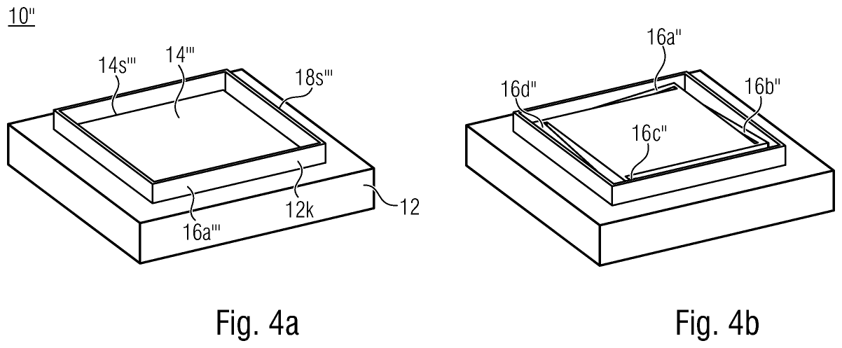

A somewhat altered configuration is illustrated in FIG. 4 where the external screen, comparable to 18s″, is uninterrupted so as to further improve sealing.

FIG. 4 shows an MEMS sound transducer 10′″ in which a sound-radiating structure 14′″ is arranged in a cavity 12k of the substrate 12. The sound-radiating structure 14′″ is comparable to the sound-radiating structure 14′″ as regards shape and position and may also comprise screens comparable to the screen 18a″. In this case, however, one or more bending actuators are provided below the sound-radiating structure 14″. These are provided with reference numerals 16a′″ to 16d′″. In contrast to the embodiment of FIG. 3, the elements are located below the sound-radiating structure 14′″ so that the area of the sound-radiating structure 14′″ is optimized further. The result is only one gap 14s′″ around the sound-radiating structure 14′″. This gap is sealed, for example, using the screen 18s′″.

The embodiment of FIG. 4 advantageously allows providing a vertical arrangement of the springs/actuators 16a′″ to 16d′″ and the sound-radiating structure 14′″. The springs/actuators 16a′″ are connected to the platform above or below the platform plane. This allows accommodating the springs/actuators 16′″ to 16d′″ without any additional are consumption, which means that sealing the gaps 14s′″ is used only between the platform 14′″ and the substrate.

It is to be mentioned here that the radiation structure discussed above does not necessarily have to be quadrangular or squared, but may also take any other shape, like a round shape, a shape of 90° segments as quadrants, or a different shape. Additionally, the radiation structure may be curved, like comprise a 3D structure.

Another embodiment provides a substrate having a plurality of radiation structures which are embedded into the substrate.

In all of the above embodiments, it would be conceivable for the screen to be integrated into the substrate. Exemplarily, the walls of the cavity may form the screen when the radiation structure, in its stroke, is located mainly within the substrate cavity, that is below the surface of the substrate. This may, for example, be achieved by biasing the radiation structure.

Another embodiment provides a micro-loudspeaker in MEMS technology, comprising:
(Rigid) platform executing a stroke movement
Platform suspended at a substrate
Separating the moveable parts by narrow gaps
Screen structure to obtain the narrow gaps also in the case of deflection.

In accordance with embodiments, the platform may be driven, for example, by piezoelectric bending actuators which at the same time form the platform suspension.

In accordance with embodiments, screen structures may be implemented on the substrate and/or the moveable platform.

In accordance with embodiments, screen structures may be implemented upwards, downwards or in both directions.

In corresponding embodiments, the platform is suspended within and above or below the platform.

Another embodiment provides a manufacturing method for manufacturing the micro-loudspeaker.

All the embodiments mentioned and discussed above are of advantage in that decoupling the drive and air displacement functions allows separately optimizing the individual components.

One field of application is generally the field of microsound transducers, that is micro-loudspeakers and microphones. However, apart from applications in the audible range (like micro-loudspeakers for consumer electronics, telecommunications and medical technology), applications in the ultrasonic range are also conceivable.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### LIST OF REFERENCES

[1] German patent application DE 10 2014 217 798, “Mikromechanische piezoelektrische Aktuatoren zur Realisierung hoher Kräfte and Auslenkungen”
[2] “Data Sheet Achelous, MEMS-based microspeaker for headphones, wearables and array applications”, USound GmbH, 2018
[3] F. Stoppel, A. Männchen, F. Niekiel, D. Beer, T. Giese, B. Wagner, “New integrated full-range MEMS speaker for in-ear applications”, IEEE Micro Electro Mechanical Systems (MEMS), 2018
[4] U.S. Pat. No. 9,237,961 B2
[5] I. Shahosseini, E. Lefeuvre, J. Moulin, E. Martincic, M. Woytasik, G. Lemarquand, IEEE Sens. J. 13 (2013), pp. 273-284
[6] F. L. Ayatollahi, B. Y. Majlis, “Materials Design and Analysis of Low-Power MEMS Microspeaker Using Magnetic Actuation Technology”, Adv. Mater. Res. 74 (2009), pp. 243-246
[7] Y. C. Chen, Y. T. Cheng, “A low-power milliwatt electromagnetic microspeaker using a PDMS membrane for hearing aids application”, IEEE Int. Conf. Micro Electro Mech. Syst., 24^{th} (2011), pp. 1213-1216
[8] M.-C. Cheng, W.-S. Huang, S. R.-S. Huang, “A silicon microspeaker for hearing instruments”, J. Micromech. Microeng. 14 (2004), pp. 859-866
[9] S.-S. Je, F. Rivas, R. E. Diaz, J. Kwon, J. Kim, B. Bakkaloglu, S. Kiaei, J. Chae, “A Compact and Low-Cost MEMS Loudspeaker for Digital Hearing Aids”, IEEE Trans. Biomed. Circ. Sys. 3 (2009), pp. 348-358
[10] B. Y. Majlis, G. Sugandi, M. M. Noor, “Compact electrodynamics MEMS-speaker”, China Semiconductor Technology International Conference (CSTIC), 2017
[11] P. R. Jadhav, Y. T. Cheng, S. K. Fan, C. Y. Liang, “A sub-mW Electromagnetic Microspeaker with Bass Enhancement using Parylene/Graphene/Parylene Composite Membrane”, IEEE Micro Electro Mechanical Systems (MEMS), 2018
[12] Albach, T. S., Horn, P., Sutor, A. & Lerch, R. Sound Generation Using a Magnetostrictive, Micro Actuator. J. Appl. Phys. 109(7), (2011)
[13] B. Kaiser, S. Langa, L. Ehrig, M. Stolz, H. Schenk, H. Conrad, H. Schenk, K Schimmanz, D. Schuffenhauer, Concept and proof for an all-silicon MEMS micro speaker utilizing air chambers, Microsystems & Nanoengineering (2019)
[14] U.S. Pat. No. 10,327,060, “Air Pulse Generating Element and Sound Producing Device”

1. An MEMS sound transducer comprising:
at least one actuator;
a radiation structure coupled to the actuator and configured as a separate element;
a structure surrounding the radiation structure, wherein the radiation structure is separated from the surrounding structure by one or more gaps; and
at least one screen arranged along at least one of the one or more gaps,
wherein the at least one screen is formed as part of the radiation structure.

2. The MEMS sound transducer in accordance with claim 1, wherein the radiation structure and the surrounding structure are arranged in one plane; and/or
wherein the surrounding structure is formed by a substrate and the radiation structure is located in or in parallel to a substrate plane or cavity of the substrate.

3. The MEMS sound transducer in accordance with claim 1, wherein the one or more gaps are provided circumferentially around the radiation structure.

4. The MEMS sound transducer in accordance with claim 1,
wherein a further screen extends into a substrate plane or perpendicularly into a substrate plane; and/or
wherein the further screen is formed as part of the surrounding structure; and
wherein the further screen extends out of the substrate plane or perpendicularly out of a substrate plane; or
wherein the further screen is formed by a cavity of the surrounding structure.

5. The MEMS sound transducer in accordance with claim 1, wherein the radiation structure is pre-deflected relative to the surrounding structure in an idle state.

6. The MEMS sound transducer in accordance with claim 1, wherein the at least one screen is arranged to be circumferential around the radiation structure or along the one or more gaps.

7. The MEMS sound transducer in accordance with claim 1, wherein the actuator comprises a bending actuator or a longitudinal bending actuator or a bending actuator comprising an aspect ratio of at least 5:1; and/or
wherein the actuator comprises a clamped end or a free end.

8. The MEMS sound transducer in accordance with claim 7, wherein the radiation structure is coupled to the free end of the bending transducer or coupled to the bending transducer in the region of the free end or coupled in the longitudinal direction of the bending transducer in the third closer to the free end than to the clamped end.

9. The MEMS sound transducer in accordance with claim 1, wherein the actuator comprises a piezoelectric actuator, electrodynamic actuator or electrostatic actuator; and/or
wherein the radiation structure is supported relative to the surrounding structure by at least one actuator, bending actuator, spring elements or springs; and/or
wherein the at least one actuator connects the radiation structure by a partially flexible structure or several partially flexible structures; and/or
wherein the radiation structure is supported relative to the surrounding structure by at least one actuator, bending actuators, spring elements or springs or is supported by several actuators, several bending actuators, several spring elements or several springs; and/or
wherein the radiation structure is supported relative to the surrounding structure by at least one actuator, bending actuator, spring elements or springs or is supported by several actuators, several bending actuators, several spring elements or several springs which extend along the gap or in the gap.

10. The MEMS sound transducer in accordance with claim 1, wherein the at least one actuator is arranged alongside or in parallel along an edge of the radiation structure.

11. The MEMS sound transducer in accordance with claim 1, wherein the radiation structure comprises two or more regions, wherein a central region is arranged between the two or more regions.

12. The MEMS sound transducer in accordance with claim 1, wherein the at least one actuator is coupled to the radiation structure in a central region; and/or
wherein the at least two actuators are coupled to the radiation structure, and wherein the at least two actuators are arranged to be opposite.

13. The MEMS sound transducer in accordance with claim 1, wherein at least one further screen extends along a gap between the at least one actuator and an edge of the radiation structure.

14. The MEMS sound transducer in accordance with claim 12, wherein the radiation structure comprises four regions arranged as quadrants,
wherein the four regions arranged as quadrants are interrupted by four suspension elements or actuators, and/or wherein the suspension elements or actuators are coupled to a central region between the four quadrants.

15. The MEMS sound transducer in accordance with claim 1, wherein the radiation structure is configured to perform, when actuated by the actuator, a stroke movement in a direction out of the substrate plane.

16. A method for manufacturing an MEMS sound transducer in accordance with claim 1, comprising:
providing at least one actuator and a radiation structure which is coupled to the actuator and configured as a separate element, and a structure surrounding the radiation structure, wherein the radiation structure is separated from the surrounding structure by one or more gaps; and
arranging at least one screen along at least one of the one or more gaps.

17. An MEMS sound transducer comprising:
at least one actuator;
a radiation structure coupled to the actuator and configured as a separate element;
a structure surrounding the radiation structure, wherein the radiation structure is separated from the surrounding structure by one or more gaps; and
at least one screen arranged along at least one of the one or more gaps,
wherein the at least one screen is formed as part of the surrounding structure and by a cavity of the surrounding structure; and wherein the at least one screen extends out of a substrate plane or perpendicularly out of a substrate plane, and wherein the at least one screen extends an edge of the cavity.
